(19) United States
(12) Patent Application Publication
(10) Pub. No.: US 2024/0027681 A1
(43) Pub. Date: Jan. 25, 2024

(54) Photoelectric Converter

(71) Applicant: Nippon Telegraph and Telephone Corporation, Tokyo (JP)

(72) Inventors: Koji Takeda, Musashino-shi, Tokyo (JP); Takuro Fujii, Musashino-shi, Tokyo (JP); Tomonari Sato, Musashino-shi, Tokyo (JP); Toshiki Kishi, Musashino-shi, Tokyo (JP); Yoshiho Maeda, Musashino-shi, Tokyo (JP); Toru Segawa, Musashino-shi, Tokyo (JP); Shinji Matsuo, (US)

(21) Appl. No.: 18/245,031

(22) PCT Filed: Sep. 15, 2020
(86) PCT No.: PCT/JP2020/034884

§ 371 Date: Mar. 13, 2023

(51) Int. Cl. G02B 6/12

(52) U.S. Cl. CPC G02B 6/12004; G02B 2006/12121

(57) ABSTRACT

A photoelectric conversion device includes a plurality of optical waveguides that are formed on a substrate and have the same waveguide direction, and a plurality of waveguide-type photoelectric conversion elements that are connected to the respective optical waveguides. The plurality of photoelectric conversion elements is arranged in the waveguide direction of the plurality of optical waveguides. In a planar view, the line segment connecting the photoelectric conversion elements adjacent to one another in the waveguide direction of the plurality of photoelectric conversion elements is inclined with respect to the waveguide direction.

### TECHNICAL FIELD

The present invention relates to a photoelectric conversion device that includes a plurality of photoelectric conversion elements.

### BACKGROUND ART

Optical interconnection is a technique using optical communication for short-distance interconnection in a chip, between chips, or between boards or the like in a device, or between devices, and is a technique for overcoming the limitations of conventional electrical connection and enabling both higher-speed operation and lower power consumption. Development of a silicon photonics technology for maximizing the advantages of this optical interconnection technique and achieving ultra-miniaturization of devices at the same time is in progress. As a light source to be used in this technology, a configuration in which a group III-V semiconductor laser is formed on a silicon substrate has been considered, for example (see Patent Literature 1).

### CITATION LIST

### Patent Literature

Patent Literature 1: JP 2019-036624 A

### Non Patent Literature

Non Patent Literature 1: H. Nishi et al., “Monolithic Integration of an 8-channel Directly Modulated Membrane-laser Array and a SiN AWG Filter on Si”, Optical Fiber Communications Conference and Exposition, 17843037, 978-1-943580-38-5, 2018.

### SUMMARY OF INVENTION

### Technical Problem

Meanwhile, to achieve optical interconnection between CPU chips, for example, a light source and a light receiving portion are designed to have a width substantially equal to the width of the CPU chips. However, in a photoelectric conversion element such as a single semiconductor laser, transmission capacity is limited, and therefore, the required transmission capacity is not ensured. To solve the shortage of transmission capacity, there is a technique by which a plurality of photoelectric conversion elements is arranged in one row (see Non Patent Literature 1). However, when a plurality of photoelectric conversion elements is arranged in one row as in this technique, the width of the photoelectric conversion elements greatly exceeds the width of CPU chips.

The present invention has been made to solve the above problem, and aims to achieve optical interconnection using a plurality of photoelectric conversion elements, without an increase in width.

### Solution to Problem

A photoelectric conversion device according to the present invention includes: a plurality of optical waveguides that are formed on a substrate and have the same waveguide direction; and a plurality of waveguide-type photoelectric conversion elements that are optically connected to the respective optical waveguides and are arranged in the waveguide direction.

### Advantageous Effects of Invention

As described above, according to the present invention, optical interconnection using a plurality of photoelectric conversion elements can be achieved without an increase in width.

### BRIEF DESCRIPTION OF DRAWINGS

FIG. 1 is a plan view illustrating a configuration of a photoelectric conversion device according to an embodiment of the present invention.

FIG. 2 is a plan view illustrating a configuration of another photoelectric conversion device according to an embodiment of the present invention.

FIG. 3A is a cross-sectional view illustrating a partial configuration of a photoelectric conversion device according to an embodiment of the present invention.

FIG. 3B is a plan view illustrating a partial configuration of a photoelectric conversion device according to an embodiment of the present invention.

FIG. 3C is a plan view illustrating a partial configuration of a photoelectric conversion device according to an embodiment of the present invention.

FIG. 4 is a plan view illustrating an example design of a photoelectric conversion device according to an embodiment of the present invention.

FIG. 5 is a plan view illustrating another example design of a photoelectric conversion device according to an embodiment of the present invention.

FIG. 6 is a plan view illustrating another example design of a photoelectric conversion device according to an embodiment of the present invention.

FIG. 7 is a plan view illustrating another example design of a photoelectric conversion device according to an embodiment of the present invention.

FIG. 8 is a plan view illustrating another example design of a photoelectric conversion device according to an embodiment of the present invention.

### DESCRIPTION OF EMBODIMENTS

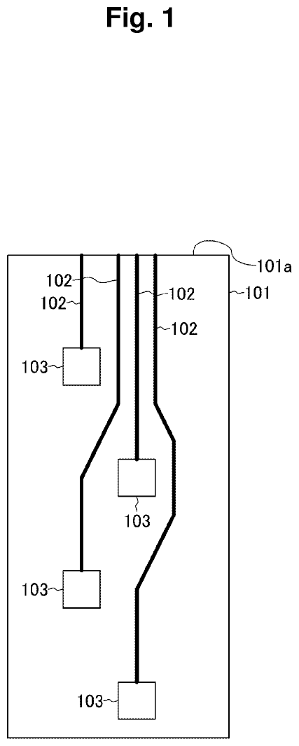

In the description below, a photoelectric conversion device according to an embodiment of the present invention is described with reference to FIG. 1. The photoelectric conversion device includes a plurality of optical waveguides 102 that are formed on a substrate 101 and have the same waveguide direction, and a plurality of waveguide-type photoelectric conversion elements 103 that are connected to the respective optical waveguides 102. The plurality of photoelectric conversion elements 103 is arranged in the waveguide direction of the plurality of optical waveguides 102.

The waveguide direction mentioned above is a vertical direction of the paper surface of FIG. 1. The light input/output ends of the plurality of optical waveguides 102 are disposed at an end portion 101a serving as the light input/output port of the photoelectric conversion device. The outer shape of the photoelectric conversion device (the substrate 101) in a planar view is normally rectangular, and the end portion 101a is one side of the rectangle. Accordingly, the light input/output ends of the plurality of optical waveguides 102 are linearly arranged. A direction intersecting (orthogonal to) the direction of this arrangement is the waveguide direction mentioned above. Further, the direction of the arrangement of the light input/output ends of the plurality of optical waveguides 102 arranged linearly is the width direction of the photoelectric conversion device (the substrate 101).

In this example, a line segment connecting the photoelectric conversion elements 103 adjacent to one another in the waveguide direction of the plurality of photoelectric conversion elements 103 is inclined with respect to the waveguide direction in a planar view. This line segment connects the center positions of the photoelectric conversion elements 103 adjacent to one another in the waveguide direction in a planar view. Note that the example described herein is an example in which the respective photoelectric conversion elements 103 are connected to four optical waveguides 102.

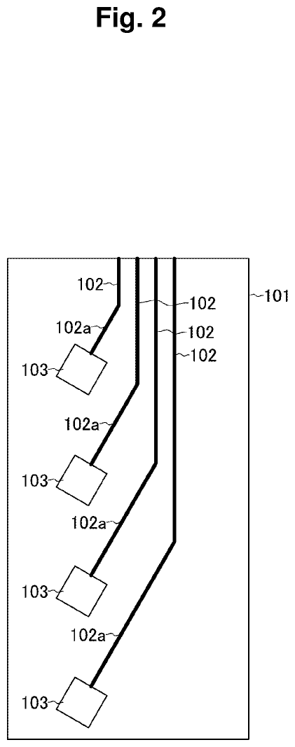

Also, as illustrated in FIG. 2, the waveguide direction of the plurality of photoelectric conversion elements 103 can be inclined with respect to the waveguide direction of the plurality of optical waveguides 102. In this case, the photoelectric conversion elements 103 are optically connected to the optical waveguide 102 via sub optical waveguides 102a. Note that the waveguide direction mentioned above is a vertical direction of the paper surface of FIG. 2.

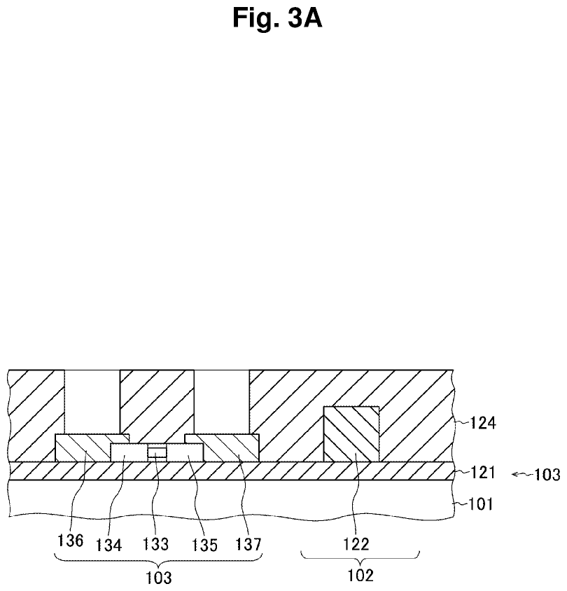

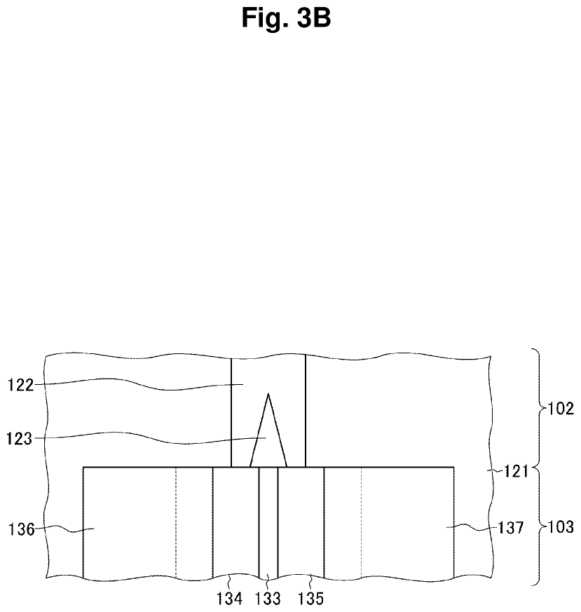

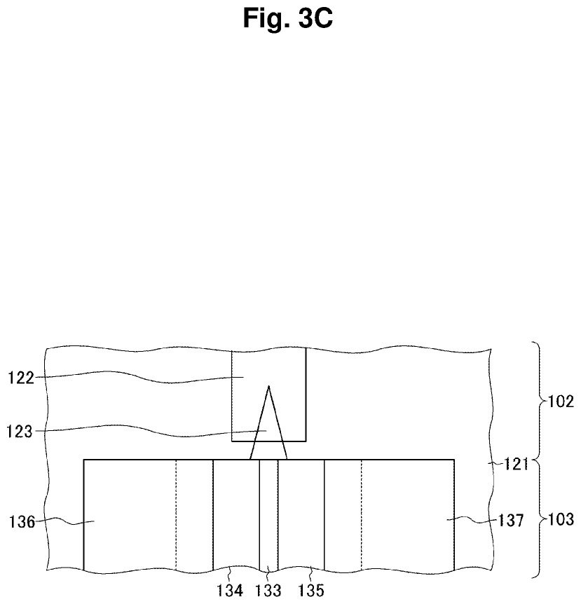

Here, as illustrated in FIG. 3A, a photoelectric conversion element 103 includes a lower cladding layer 121 formed on the substrate 101 formed with single-crystal Si, an active layer (a core) 133 formed on the lower cladding layer 121, a p-type semiconductor layer 134, an n-type semiconductor layer 135, a first electrode 136, and a second electrode 137.

The lower cladding layer 121 is formed with SiO₂, for example, and has a flat surface. The active layer 133 is formed with an InP-based compound semiconductor, for example. The active layer 133 has a multiple quantum well structure in which well layers formed with GaInAs and barrier layers are alternately stacked, for example. The active layer 133 has a length of about 140 μm in the waveguide direction, and a width of about 0.8 μm in a cross-section perpendicular to the waveguide direction, for example.

The p-type semiconductor layer 134 and the n-type semiconductor layer 135 are formed with an InP-based compound semiconductor, for example, and are designed to sandwich the active layer 133 on the lower cladding layer 121. In this example, the p-type semiconductor layer 134 and the n-type semiconductor layer 135 are designed to sandwich the active layer 133 in the planar direction of the surface of the lower cladding layer 121. The first electrode 136 is electrically connected to the p-type semiconductor layer 134, and the second electrode 137 is electrically connected to the n-type semiconductor layer 135.

An electric current is applied to the active layer 133 from the p-type semiconductor layer 134 and the n-type semiconductor layer 135, and the light being guided with the active layer 133 serving as the core is modulated, for example. Also, an electric current is applied to the active layer 133 from the p-type semiconductor layer 134 and the n-type semiconductor layer 135, and laser light is oscillated from the active layer 133 equipped with a resonator such as a diffraction grating, for example. The active layer 133 extends by a predetermined length in the light-emitting direction, for example, and a diffraction grating can be formed on the active layer 133 in a predetermined region in the extending direction.

Further, the active layer 133 may be formed with a material that absorbs light having the target wavelength, and a voltage in a reverse direction is applied to the p-type semiconductor layer 134 and the n-type semiconductor layer 135, so that the light being guided can be received.

The optical waveguide 102 optically connected to the photoelectric conversion element 103 includes a core 122 formed with SiOₓ, and the optical waveguide 102 that is the core 122 formed with SiOₓ is disposed on the side of the photoelectric conversion element 103, for example. Further, an upper cladding 124 is formed over the core 122 and the photoelectric conversion element 103. The shape of the core 122 in a cross-section perpendicular to the waveguide direction is a rectangle having a width of about 3 μm and a height of about 3 μm, for example. The same applies to the sub optical waveguides 102a. Further, the photoelectric conversion element 103 and the optical waveguide 102 (the sub optical waveguide 102a) are optically connected by a spot size converter using a tapered core 123 formed with InP, for example. The length of the tapered core 123 in the waveguide direction can be about 300 μm. Also, the length of the spot size converter in the waveguide direction can be about 300 μm.

In a photoelectric conversion device according to the embodiment described above, a plurality of photoelectric conversion elements is arranged in the waveguide direction. Accordingly, the plurality of photoelectric conversion elements can be efficiently arranged within a limited width of the subject device, and the transmission capacity per unit length (width) can be increased. Note that the “width” mentioned herein is a dimension in a direction perpendicular to the waveguide direction on the surface of the substrate.

Note that a plurality of sets of the plurality of optical waveguides and the plurality of photoelectric conversion elements described above can be arranged in a direction intersecting the waveguide direction. For example, a plurality of sets of the plurality of optical waveguides and the plurality of photoelectric conversion elements described above can be arranged in a direction perpendicular to the waveguide direction.

In the description below, explanation will be made through examples.

### Example 1

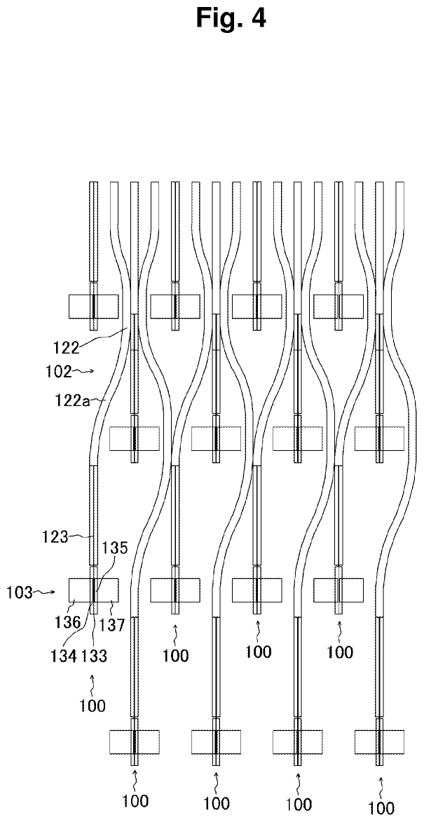

First, Example 1 is described with reference to FIG. 4. In this example design, eight sets 100 of a plurality of optical waveguides 102 arranged in the waveguide direction and a plurality of photoelectric conversion elements 103 are arranged in a direction intersecting the waveguide direction. In this example, the photoelectric conversion elements 103 are arranged in four rows and four columns in a planar view. By increasing the number of columns in the direction intersecting the waveguide direction, it is possible to shorten the length of the device in the waveguide direction, though the width of the entire device becomes greater. Here, the shortest distance between cores 122 adjacent to each other in the waveguide direction is set to about 23 μm, so that crosstalk between adjacent optical waveguides 102 can be reduced. Note that the bending radius of a bent portion 122a of a core 122 is about 500 μm.

### Example 2

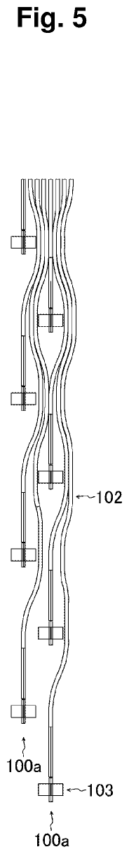

Next, Example 2 is described with reference to FIG. 5. In this example design, two sets 100a of a plurality of optical waveguides 102 arranged in the waveguide direction and a plurality of photoelectric conversion elements 103 are arranged in a direction intersecting the waveguide direction. In this example, the photoelectric conversion elements 103 are arranged in eight rows and two columns in a planar view. By reducing the number of columns in the direction intersecting the waveguide direction, it is possible to further reduce the width of the entire device.

### Example 3

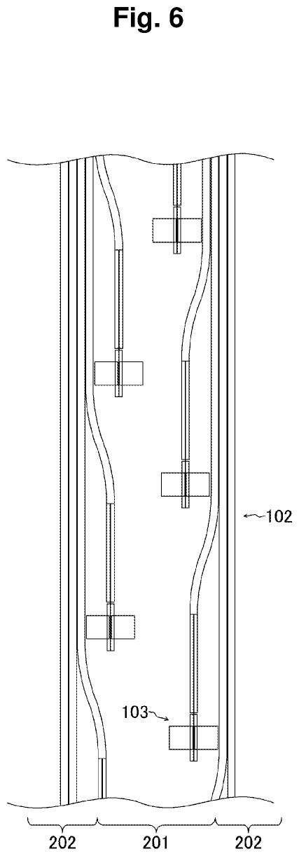

Next, Example 3 is described with reference to FIG. 6. In this example design, in a set of a plurality of optical waveguides 102 arranged in the waveguide direction and a plurality of photoelectric conversion elements 103, a first placement region 201 of the plurality of photoelectric conversion elements 103 is set at the center of the device, and second placement regions 202 of the plurality of optical waveguides 102 are set on both sides of the first placement region.

### Example 4

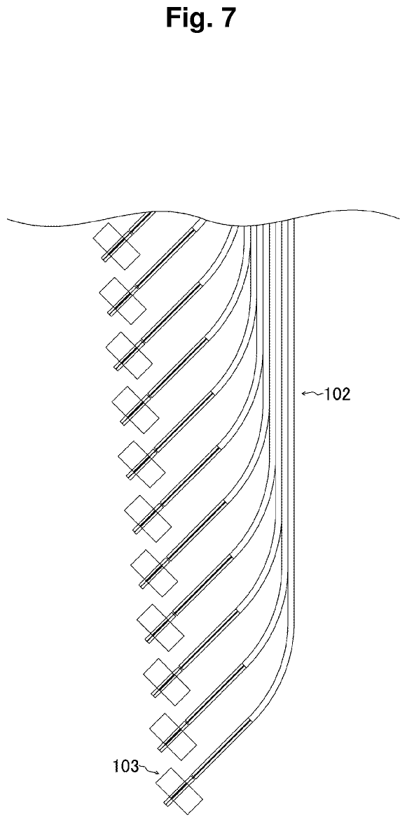

Next, Example 4 is described with reference to FIG. 7. In this example design, the waveguide direction of a plurality of photoelectric conversion elements 103 is inclined by 45° with respect to the waveguide direction of a plurality of optical waveguides 102. In this case, the photoelectric conversion elements 103 having an active layer length of about 140 μm can be arranged at intervals of about 200 μm in the waveguide direction. In a case where 16 photoelectric conversion elements 103 are arranged in the waveguide direction in this configuration, the size of the device (a chip) in a planar view can be about 900 μm in width and about 3800 μm in length in the waveguide direction.

### Example 5

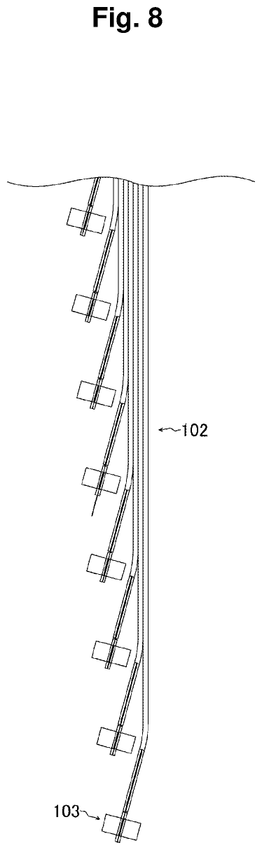

Next, Example 5 is described with reference to FIG. 8. In this example design, the waveguide direction of a plurality of photoelectric conversion elements 103 is inclined by 15° with respect to the waveguide direction of a plurality of optical waveguides 102. In this case, the photoelectric conversion elements 103 having an active layer length of about 140 μm can be arranged at intervals of about 400 μm in the waveguide direction. In a case where 16 photoelectric conversion elements 103 are arranged in the waveguide direction in this configuration, the size of the device (a chip) in a planar view can be about 600 μm in width and about 6800 μm in length in the waveguide direction. According to Example 5, the width of the device can be made even smaller than that in Example 4.

As described above, according to the present invention, waveguide-type photoelectric conversion elements optically connected to the respective optical waveguides of a plurality of optical waveguides having the same waveguide direction are arranged in the waveguide direction. Thus, it is possible to achieve optical interconnection using the plurality of photoelectric conversion elements, without an increase in the width.

Note that the present invention is not limited to the embodiments described above, and it is obvious that many modifications and combinations can be implemented by a person having ordinary knowledge in the art within the technical idea of the present invention.

### REFERENCE SIGNS LIST

101 substrate
102 optical waveguide
103 photoelectric conversion element

1. A photoelectric conversion device comprising:
a plurality of optical waveguides that are formed on a substrate and have same waveguide direction; and
a plurality of waveguide-type photoelectric conversion elements that are optically connected to the respective optical waveguides of the plurality of optical waveguides and are arranged in the waveguide direction.

2. The photoelectric conversion device according to claim 1, wherein
a line segment that connects photoelectric conversion elements adjacent to each other in the waveguide direction of the plurality of photoelectric conversion elements is inclined with respect to the waveguide direction in a planar view.

3. The photoelectric conversion device according to claim 1, wherein
the waveguide direction of the plurality of photoelectric conversion elements is inclined with respect to the waveguide direction of the plurality of optical waveguides.

4. The photoelectric conversion device according to claim 1, wherein
a plurality of sets of the plurality of optical waveguides and the plurality of photoelectric conversion elements is arranged in a direction intersecting the waveguide direction.

5. The photoelectric conversion device according to claim 2, wherein
a plurality of sets of the plurality of optical waveguides and the plurality of photoelectric conversion elements is arranged in a direction intersecting the waveguide direction.

6. The photoelectric conversion device according to claim 3, wherein
a plurality of sets of the plurality of optical waveguides and the plurality of photoelectric conversion elements is arranged in a direction intersecting the waveguide direction.
